(19) United States
(12) Patent Application Publication
(10) Pub. No.: US 2012/0169349 A1
(43) Pub. Date: Jul. 5, 2012

(54) CURRENT TEST SYSTEM FOR HARD DISK DRIVE AND ADAPTER BOARD THEREOF

(75) Inventors: WEN-SEN HU, Shenzhen City (CN); GUO-YI CHEN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/053,296

(22) Filed: Mar. 22, 2011

(30) Foreign Application Priority Data
Dec. 29, 2010 (CN) 201010612704.6

(51) Int. Cl. G01R 31/02

(52) U.S. Cl. 324/537

(57) ABSTRACT

A current test system for a hard disk drive includes an adapter board, a test device, two cables and two current clamps. The hard disk drive is connected to the test device through the adapter board. The two cables are connected to two power routes of the adapter board, respectively. While the test device tests the hard disk drive through the adapter board, the two current clamps respectively clamp the two cables to determine the current through the two power routes.

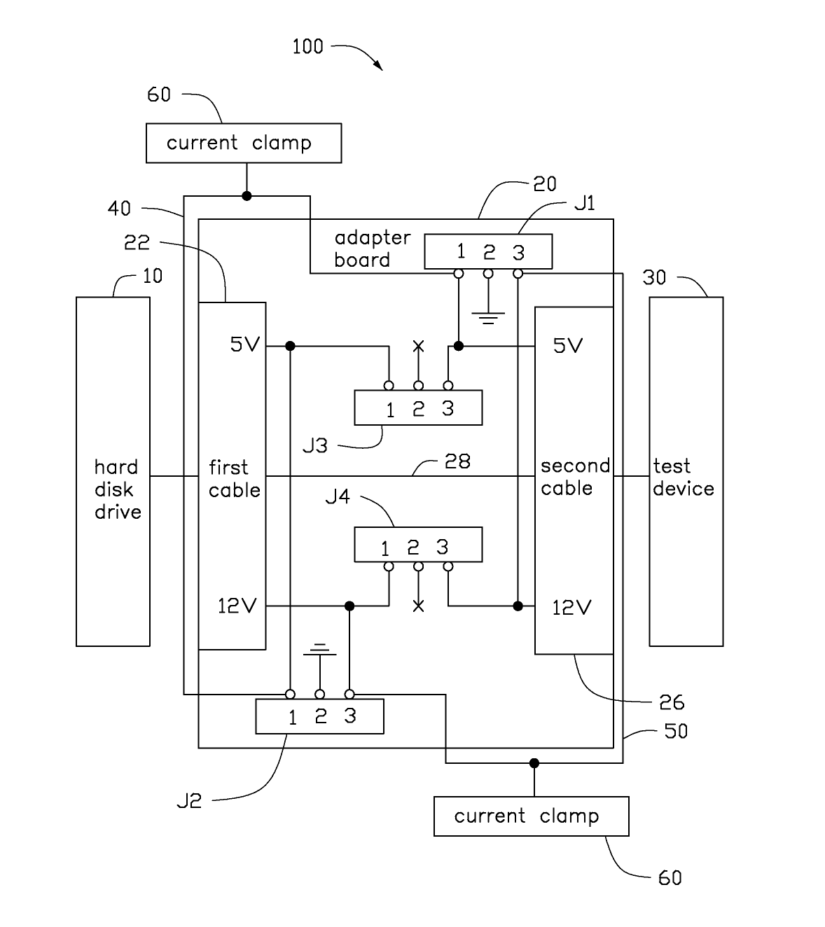

### BACKGROUND

1. Technical Field

The present disclosure relates to a current test system for a hard disk drive and an adapter board thereof

2. Description of Related Art

For ensuring the quality of hard disk drives, a series of tests have to be performed following assembly. However, since conventional tests do not determine current in a hard disk drive, detailed parameters such as current variation during data access cannot be obtained.

### BRIEF DESCRIPTION OF THE DRAWINGS

Many aspects of the present disclosure can be better understood with reference to the following drawing. The components in the drawing are not necessarily drawn to scale, the emphasis instead being placed upon clearly illustrating the principles of the present disclosure. Moreover, in the drawing, like reference numerals designate corresponding parts throughout the several views.

The figure is a block diagram of a preferred embodiment of a current test system for a hard disk drive of the present disclosure.

### DETAILED DESCRIPTION

As shown in the figure, a preferred embodiment of the current test system for a hard disk drive of the present disclosure includes a hard disk drive 10, an adapter board 20, a test device 30, a first cable 40, a second cable 50, and two current clamps 60.

The adapter board 20 includes a first interface 22, a second interface 26, a bus 28, and two connectors J1 and J2. Each of the two connectors J1 and J2 includes three pins 1-3 which can be connected to each other by jumpers or cables. The first interface 22 is connected to an interface of the hard disk drive 10. The second interface 26 is connected to a corresponding interface of the test device. Pin 1 of the connector J1 is connected to a 5V power pin of the second interface 26; pin 2 of the connector J1 is grounded; and pin 3 of the connector J1 is connected to a 12V power pin of the second interface 26. Pin 1 of the connector J2 is connected to the 5V power pin of the first interface 22; pin 2 of the connector J2 is grounded; and pin 3 of the connector J2 is connected to the 12V power pin of the first interface 22. The communication pin of the first interface 22 is connected to the corresponding communication pin of the second interface 26 through the bus 28.

In this embodiment, the hard disk drive can be a 2.5-inch SATA (Serial Advanced Technology Attachment) hard disk drive, a 3.5-inch SATA hard disk drive, a 2.5-inch SAS (Serial Attached Small Computer System Interface) hard disk drive, or a 3.5-inch SAS hard disk drive. The first interface 22 and the second interface 26 are SAS interfaces. Since SAS interface is downward compatible to SATA interface and SATA hard disk drive can be used in SAS environment, the first interface 22 is adaptable to a SATA hard disk drive or a SAS hard disk drive. The test device 30 is a personal computer or a server with software for testing hard disk drives. Since the test device 30 merely provides 5V power and 12V power to the hard disk drive 10, various voltages such as 1.8V, 2.5V, 3.3V, or 8V power for the normal operation of the hard disk drive 10 are provided utilizing a corresponding circuit to transform the 5V and the 12V power. Consequently, the current in the hard disk drive 10 can be determined by the current through the 5V and the 12V routes.

When determining the current in the hard disk drive 10 during testing, the interface of the hard disk drive 10 is connected to the first interface 22 of the adapter board 20. The corresponding interface of the test device 30 is connected to the second interface 26 of the adapter board 20. Pin 1 of the connector J1 is connected to pin 1 of the connector J2 through the first cable 40. Pin 3 of the connector J1 is connected to pin 3 of the connector J2 through the second cable 50. The 5V power output by the test device 30 is provided to the hard disk drive through the 5V power pin of the second interface 26, pin 1 of the connector J1, the first cable 40, pin 1 of the second connector J2, and the 5V power pin of the first interface 22. The 12V power output by the test device 30 is provided to the hard disk drive 10 through the 12V power pin of the second interface 26, pin 3 of the connector J1, the second cable 50, pin 3 of the connector J2, and the 12V power pin of the first interface 22. After providing power to the hard disk drive 10, the test device 30 communicates with the hard disk drive 10 through the second interface 26, the bus 28, and the first interface 22 to test the hard disk drive. During testing, the two current clamps 60 clamp the first cable 40 and the second cable 50, respectively, to determine the current through the 5V power route and the 12V power route of the hard disk drive 10.

In this embodiment, the adapter board 20 further includes two connectors J3 and J4. Each of the two connectors J3 and J4 includes three pins 1-3 which can be connected to each other by jumpers or cables. Pin 1 of the connector J3 is connected to the 5V power pin of the first interface 22; pin 2 of the connector J3 is idle; pin 3 of the connector J3 is connected to the 5V power pin of the second interface 26. Pin 1 of the connector J4 is connected to the 12V power pin of the first interface 22; pin 2 of the connector J4 is idle; and pin 3 of the connector J4 is connected to the 12V power pin of the second interface 26.

When merely testing the hard disk drive 10 without determining the current therein, pin 1 of the connector J1 is disconnected from pin 1 of the connector J2, and pin 3 of the connector J1 is disconnected from pin 3 of the connector J2. Pin 1 and pin 3 of the connector J3 are connected to each other and pin 1 and pin 3 of the connector J4 are connected to each other by two jumpers (not shown), respectively. The 5V power output by the test device 30 is provided to the hard disk drive 10 through the 5V power pin of the second interface 26, the connector J3, and the 5V power pin of the first interface 22. The 12V power output by the test device 30 is provided to the hard disk drive 10 through the 12V power pin of the second interface 26, the connector J4, and the 12V power pin of the first interface 22. After providing power to the hard disk drive 10, the test device 30 communicates with the hard disk drive 10 through the second interface 26, the bus 28, and the first interface 22 to test the hard disk drive. However, in other embodiments, the two connectors J3 and J4 can be omitted.

The current test system 100 for a hard disk drive of the present disclosure can test 2.5-inch SATA hard disk drive, 3.5-inch SATA hard disk drive, 2.5-inch SAS hard disk drive, and 3.5-inch SAS hard disk drive by utilizing SAS interface to implement the first interface 22 and the second interface 26 of the adapter board 20. In addition, the 5V and the 12V power signals of the adapter board 20 are conducted through the two connectors J1 and J2, and a circuit is formed through the first cable 40 and the second cable 50 so that the current in the hard disk drive 10 can be determined by clamping the two current clamps 60 around the first cable 40 and the second cable 50. Furthermore, the test of the hard disk drive 10 can be performed without the first cable 40 and the second cable 50 by the two connectors J3 and J4.

While the disclosure has been described by way of example and in terms of preferred embodiment, it is to be understood that the disclosure is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A current test system for a hard disk drive comprising:
a hard disk drive;
a first and a second cable;
an adapter board comprising:
a first and a second interface, wherein the first interface is connected to the hard disk drive, the second interface connected to the test device includes a first and a second power pin;
a first and a second connector including a first and a second pin, wherein the first pin of the first connector is connected to the first power pin of the second interface, the second pin of the first connector is connected to the second power pin of the second interface, the first pin of the second connector is connected to the first power pin of the first interface and connected to the first pin of the first connector through the first cable, the second pin of the second connector is connected to the second power pin of the first interface and connected to the second pin of the first connector through the second cable; and
a bus, wherein the first interface is connected to second interface through the bus;
a test device including a first and a second power supply, wherein the first power supply provides power to the hard disk drive through the first power pin of the second interface, the first pin of the first connector, the first cable, the first pin of the second connector, and the first power pin of the first interface, the second power supply provides power to the hard disk drive through the second power pin of the second interface, the second pin of the first connector, the second cable, the second pin of the second connector, and the second power pin of the first interface, the test device communicates with the hard disk drive through the second interface, the bus, and the first interface to test the hard disk drive; and
two current clamps, wherein two current clamps clamp the first and the second cable, respectively, to determine the current through the first and the second cable.

2. The current test system of claim 1, wherein the first and the second interfaces are SAS interfaces.

3. The current test system of claim 1, wherein the hard disk drive is a 2.5-inch SATA hard disk drive, a 3.5-inch SATA hard disk drive, a 2.5-inch SAS hard disk drive, or a 3.5-inch SAS hard disk drive.

4. The current test system of claim 1, wherein the adapter board further comprising a third and a fourth interface, the third and the fourth interface includes a first and a second pin, the first pin of the third connector is connected to the first power pin of the first interface, the second pin of the third connector is connected to the first power pin of the second interface, the first pin of the fourth connector is connected to the second power pin of the first interface, the second pin of the fourth connector is connected to the second power pin of the second interface, wherein when the first pin of the first connector is disconnected from the first pin of the second connector and the second pin of the first connector is disconnected from the second pin of the second connector, the first pin and the second pin of the third connector are connected to each other and the first pin and the second pin of the fourth connector are connected to each other by two jumpers, respectively, the first power supply of the test device provides power to the hard disk drive through the first power pin of the second interface, the third connector, and the first power pin of the first interface, the second power supply of the test device provides power to the hard disk drive through the second power pin of the second interface, the fourth connector, and the second power pin of the first interface, the test device communicates with the hard disk drive through the second interface, the bus, and the first interface to test the hard disk drive.

5. The current test system of claim 1, wherein the first power supply of the test device is a 5V power supply, the second power supply of the test device is a 12V power supply.

6. An adapter board comprising:
a first and a second interface, wherein the first interface is connected to a hard disk drive, the second interface connected to a test device includes a first and a second power pin;
a first and a second connector including a first and a second pin, wherein the first pin of the first connector is connected to the first power pin of the second interface, the second pin of the first connector is connected to the second power pin of the second interface, the first pin of the second connector is connected to the first power pin of the first interface and connected to the first pin of the first connector through a first cable, the second pin of the second connector is connected to the second power pin of the first interface and connected to the second pin of the first connector through a second cable; and
a bus, wherein the first interface is connected to second interface through the bus;
wherein a first power supply of the test device provides power to the hard disk drive through the first power pin of the second interface, the first pin of the first connector, the first cable, the first pin of the second connector, and the first power pin of the first interface, the second power supply of the test device provides power to the hard disk drive through the second power pin of the second interface, the second pin of the first connector, the second cable, the second pin of the second connector, and the second power pin of the first interface, the test device communicates with the hard disk drive through the second interface, the bus, and the first interface to test the hard disk drive, two current clamps clamp the first and the second cable, respectively, to determine the current through the first and the second cable.

7. The adapter board of claim 6, wherein the first and the second interfaces are SAS interfaces.

8. The adapter board of claim 6, wherein the adapter board further comprising a third and a fourth interface, the third and the fourth interface includes a first and a second pin, the first pin of the third connector is connected to the first power pin of the first interface, the second pin of the third connector is connected to the first power pin of the second interface, the first pin of the fourth connector is connected to the second power pin of the first interface, the second pin of the fourth connector is connected to the second power pin of the second interface, wherein when the first pin of the first connector is disconnected from the first pin of the second connector and the second pin of the first connector is disconnected from the second pin of the second connector, the first pin of the third connector is connected to the second pin thereof and the first pin of the fourth connector is connected to the second pin thereof through two jumpers, respectively, the first power supply of the test device provides power to the hard disk drive through the first power pin of the second interface, the third connector, and the first power pin of the first interface, the second power supply of the test device provides power to the hard disk drive through the second power pin of the second interface, the fourth connector, and the second power pin of the first interface, the test device communicates with the hard disk drive through the second interface, the bus, and the first interface to test the hard disk drive.
